(19) United States
(12) Patent Application Publication
(10) Pub. No.: US 2015/0280051 A1
(43) Pub. Date: Oct. 1, 2015

(54) DIFFUSER HEAD APPARATUS AND METHOD OF GAS DISTRIBUTION

(71) Applicant: TSMC SOLAR LTD., Taichung City (TW)

(72) Inventor: Li XU, Taichung City (TW)

(73) Assignee: TSMC SOLAR LTD., Taichung City (TW)

(21) Appl. No.: 14/231,783

(22) Filed: Apr. 1, 2014

(51) Int. Cl. H01L 31/18; C23C 16/455

(52) U.S. Cl. CPC H01L 31/1884; C23C 16/45512; C23C 16/45565; C23C 16/45574

(57) ABSTRACT

An apparatus and method of forming a top contact layer of a thin film solar cell with improved layer thickness uniformity. Apparatus comprises a diffusion head for introduction of a processing gas into a chamber. The diffusion head includes a diffusion plate with a plurality of openings, each opening having a first cylindrical portion and a second conical-frustum portion.

### BACKGROUND

This disclosure relates to thin film solar cell fabrication. Chemical vapor deposition (CVD) of films is extensively used in the solar cell industry for fabricating thin film solar cells. Thin film solar cells, also known as thin film photovoltaic cells, are used to convert light energy directly into electrical current. The manufacture of thin film solar cells includes the steps of sequentially depositing one or more thin film layers onto a substrate. A thin film solar cell usually includes a bottom layer (also referred to as a substrate or carrier), a back electrode layer, an absorber layer, a buffer layer, and top contact layer. Many thin film solar cells use a “CIGS-based” absorber in the absorber layer, where “CIGS” generally refers to Copper-Indium-Gallium-Selenide or Cu(In,Ga)Se₂. The top contact layer is typically formed from a transparent conductive oxide (TCO) formed by CVD.

The deposition process is generally performed in a reactive chamber. Inside the chamber, reactant processing gasses for film formation are introduced through a diffuser over a substrate, solar cell, or semiconductor wafer.

Non-uniformity of a chemical vapor deposited film in the desired areas can induce non-uniform physical, optical and electrical properties of the deposited film, which reduce the power yield of the solar cell modules. For example, deposition of a film thickness on the order of Angstroms or nanometer should be precisely controlled.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-section view of an exemplary chemical vapor deposition system having a diffuser head in accordance with some embodiments.

FIG. 2 is a schematic cross-section view of an exemplary diffuser head opening in accordance with some embodiments.

FIG. 3 is a plan view illustrating the configuration of diffuser head openings in accordance with some embodiments.

FIG. 4 is a plan view of a portion of a diffuser head illustrating the configuration of diffuser head openings in accordance with some embodiments.

FIG. 5 is a flow chart of a method of forming a thin film solar cell using the disclosed diffuser head in accordance with some embodiments.

FIG. 6 is a flow chart of a method of forming a thin film solar cell using the disclosed diffuser head in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides a diffuser head for use with a metal organic chemical vapor deposition (MOCVD) system of fabrication of a thin film solar cell. In some embodiments, the diffuser head comprises a first plate, second plate having a plurality of openings, and a supply plenum.

The present disclosure further provides a method of forming a top contact layer of a thin film solar cell with improved layer thickness uniformity as well as improved optical and electrical properties.

Thin film solar cells include a top contact layer typically comprise a transparent conductive oxide formed by CVD (e.g., by MOCVD). Non-uniform deposition of the top contact layer degrades solar cell performance in two ways: both the optical transmittance of the top contact and the series resistance of the solar cell depend on the thickness of the TCO material. Thus, non-uniformity of the TCO can affect both these characteristics Solar cell performance can be evaluated during post-manufacturing quality assurance processes which measure top contact layer thickness, solar cell transmittance, haze, and resistivity.

Solar cells which are connected in series are particularly sensitive to variations in resistivity because current flow is limited by the highest resistivity cell connected in the series. Therefore, it is desirable to manufacture a thin film solar cell with a uniformly deposited top contact layer resulting in low variation of the solar cell properties of top contact layer thickness, solar cell transmittance, haze, and resistivity.

The disclosed apparatus and related method are provided to increase uniformity of processing gas emitted from the diffuser head and to thus allow a more uniform distribution of material deposited on a substrate during MOCVD processes, for example during the deposition of a transparent conductive oxide (TCO) layer during thin film solar cell manufacturing.

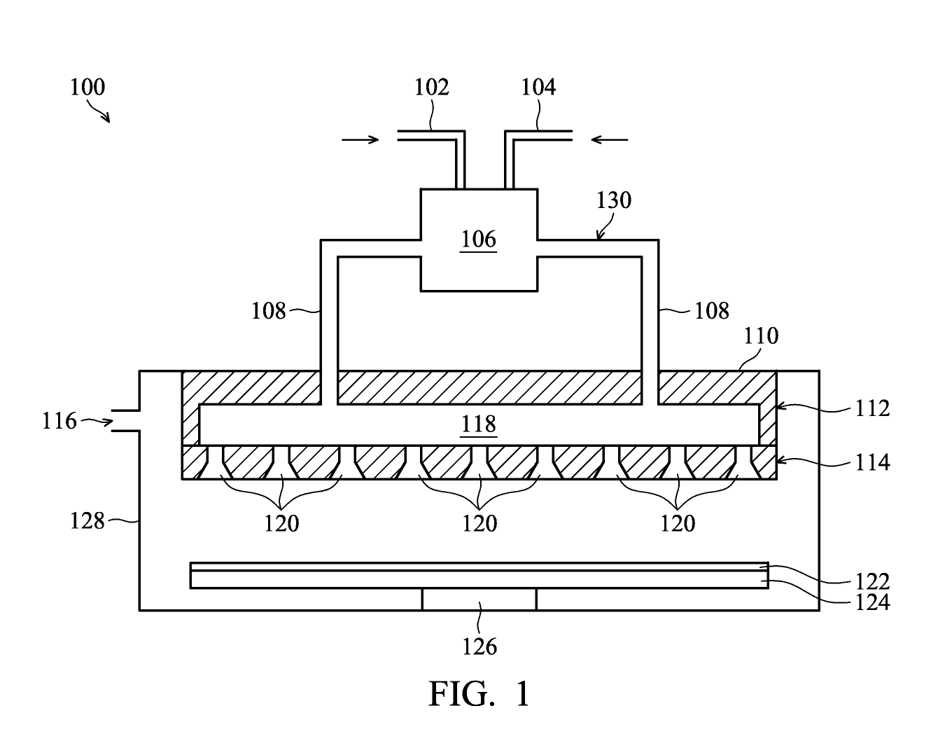

FIG. 1 is a schematic cross-section view of an exemplary MOCVD system 100 having a diffuser head 110 in accordance with some embodiments.

In FIG. 1, the exemplary MOCVD system 100 comprises a processing gas system 130, a diffuser head 110, a chamber 128, and stage 124. Diffuser head 110 and stage 124 are configured to be mounted inside chamber 128. A substrate 122 is disposed on stage 124.

Processing gas system 130 comprises a first inlet 102, second inlet 104, mixing plenum 106, and a pair of inlet channels 108. First inlet 102 and second inlet 104 are configured to be connected to at least one processing gas source and to carry processing gas from the at least one processing gas source to the mixing plenum 106. In some embodiments, first inlet 102 and second inlet 104 are connected to the same processing gas source. In other embodiments, first inlet 102 and second inlet 104 are connected to different processing gas sources. In some embodiments, the different processing gasses are mixed in the mixing plenum 106. In still further embodiments, two or more chemicals in a gas state are supplied to either or both of first inlet 102 and second inlet 104.

Inlet channels 108 carry processing gas from the mixing plenum 106 to the supply plenum 118 of diffuser head 110.

Diffuser head 110 is a gas distribution apparatus configured to provide a processing gas onto a substrate 122 inside chamber 128. Diffuser head 110 comprises a first plate 112, a second plate 114, and a supply plenum 118. Supply plenum 118 is fluidly coupled to inlet channels 108 and configured to supply a processing gas to chamber 128.

First plate 112 is coupled to second plate 114. First plate 112 is configured to have inlet channels 108 pass through first plate 112 such that inlet channels 108 and supply plenum 118 are fluidly coupled. In some embodiments, first plate 112 is mounted at or near the top of chamber 128. For example, in some embodiments, first plate 112 is mounted to the top of chamber 128

Second plate 114 has a plurality of openings 120 for allowing the flow of processing gas from the supply plenum 118 to chamber 128.

Supply plenum 118 is defined by first plate 112 and second plate 114. In some embodiments, first plate 112 defines the top and sides of supply plenum 118 while second plate 114 defines the bottom of supply plenum 118.

Stage 124 is mounted in chamber 128 by stage support 126. Stage 124 may comprise an electro-static chuck, vacuum system, clamp or other apparatus that is able to keep substrate 122 substantially on stage 124. In some embodiments, stage 124 further comprises a bottom electrode coupled to a power supply to enhance plasma within chamber 128. In some embodiments, stage 124 comprises a heater (not shown) for heating the substrate 122. The substrate 122 can be also heated by radiant heating through a quartz window (not shown) at the bottom of chamber 128.

Chamber 128 further includes a vacuum port 116, which is used to evacuate the chamber 128 of processing gas following the MOCVD process. In some embodiments, vacuum port 116 is connected to a vacuum pump (not pictured) which is configured to draw and maintain a vacuum in chamber 128.

In some embodiments, substrate 122 is a partially-fabricated thin film solar cell. For example, substrate 122 can be a partially-fabricated thin film solar cell comprising a bottom layer, back contact layer, absorber layer, and buffer layer. In other embodiments, substrate 122 comprises a substrate material such as glass, soda lime glass, or a flexible metal foil or polymer (e.g., a polyimide, polyethylene terephthalate (PET), or polyethylene naphthalene (PEN)), or any other suitable substrate. In still further embodiments, substrate 122 is a semiconductor substrate such as a silicon substrate, a III-V semiconductor compound, a glass substrate, a liquid crystal display (LCD) substrate, or any other suitable substrate.

Back contact layer includes any suitable back contact material, such as metal. In some embodiments, back contact layer can include molybdenum (Mo), platinum (Pt), gold (Au), silver (Ag), nickel (Ni), or copper (Cu). Other embodiments include still other back contact materials. In some embodiments, the back contact layer is from about 50 nm to about 2 μm thick.

In some embodiments, absorber layer includes any suitable absorber material, such as a p-type semiconductor. In some embodiments, the absorber layer can include a chalcopyrite-based material comprising, for example, Cu(In,Ga)Se₂ (CIGS), cadmium telluride (CdTe), CulnSe₂ (CIS), CuGaSe₂ (CGS), Cu(In,Ga)Se₂ (CIGS), Cu(In,Ga)(Se,S)₂ (CIGSS), CdTe or amorphous silicon. Other embodiments include still other absorber materials. In some embodiments, the absorber layer is from about 0.3 μm to about 3 μm thick.

Buffer layer includes any suitable buffer material, such as n-type semiconductors. In some embodiments, buffer layer can include cadmium sulphide (CdS), zinc sulphide (ZnS), zinc selenide (ZnSe), indium(III) sulfide (In₂S₃), indium selenide (In₂Se₃), or Zn₁₋ₓMgₓO, (e.g., ZnO). Other embodiments include still other buffer materials. In some embodiments, the buffer layer is from about 1 nm to about 500 nm thick.

In further embodiments, substrate 122 can be a partially-fabricated thin film solar cell comprising a bottom layer, back contact layer, and absorber layer. In such embodiments, both the buffer layer and the top contact layer are formed using MOCVD in chamber 128.

In some embodiments, the partially-fabricated thin film solar cell also includes an interconnect structure that includes two scribe lines, referred to as P1 and P2. The P1 scribe line extends through the back contact layer and is filled with the absorber layer material. The P2 scribe line extends through the buffer layer and the absorber layer, and contacts the back contact of the next adjacent solar cell. During formation of the top contact layer, the P2 scribe line is filled with the top contact layer material forming the series connection between adjacent cells. Following formation of the top contact layer, a third scribe line, referred to as P3, is added. The P3 scribe line extends through the top contact layer, buffer layer and absorber layer.

In some embodiments, diffuser head 110 is disposed vertically above stage 124. In other embodiments, chamber 128 is oriented horizontally (i.e. rotated 90 degrees from the position in FIG. 1) such that diffuser head 110 is disposed to the side of stage 124.

In some embodiments, processing gas is a gas comprising at least one chemical. Processing gas can be, for example, a pure chemical gas, a mixed chemical gas, a mist or suspension of chemical, an ionized gas constituting a plasma, a mixture of gas comprising liquid drops, or any other type of chemicals suitable for deposition or etching during fabrication of a thin film solar cell or semiconductor.

In use, processing gas enters via either or both of first inlet 102 and second inlet 104 and flows into mixing plenum 106. The processing gas then flows via inlet channels 108 into supply plenum 118, and then through openings 120 and into chamber 128. In chamber 128, the processing gas is deposited on or otherwise reacts with substrate 122.

The film deposited on substrate 122 can be any suitable thin film. Examples of films deposited on substrate 122 include, but are not limited to, transparent conductive oxides (TCOs), amorphous silicon (α-Si), polycrystalline silicon, silicon nitride as gate dielectric, silicone dioxide, and a metallic layer.

In some embodiments, the charge carrier density of the TCO layer can be from about 1×10¹⁷ cm⁻³ to about 1×10^{<1} cm⁻³. The TCO material for the annealed TCO layer can include suitable top contact materials, such as metal oxides and metal oxide precursors. In some embodiments, the TCO material can include AZO, GZO, AGZO, BZO or the like) AZO: alumina doped ZnO; GZO: gallium doped ZnO; AGZO: alumina and gallium co-doped ZnO; BZO: boron doped ZnO. In other embodiments, the TCO material can be cadmium oxide (CdO), indium oxide (In₂O₃), tin dioxide (SnO₂), tantalum pentoxide (Ta₂O₅), gallium indium oxide (GaInO₃), (CdSb₂O₃), or indium oxide (ITO). The TCO material can also be doped with a suitable dopant.

In some embodiments, ZnO can be doped with any of aluminum (Al), gallium (Ga), boron (B), indium (In), yttrium (Y), scandium (Sc), fluorine (F), vanadium (V), silicon (Si), germanium (Ge), titanium (Ti), zirconium (Zr), hafnium (Hf), magnesium (Mg), arsenic (As), or hydrogen (H). In other embodiments, SnO₂ can be doped with antimony (Sb), F, As, niobium (Nb), or tantalum (Ta). In other embodiments, In₂O₃ can be doped with tin (Sn), Mo, Ta, tungsten (W), Zr, F, Ge, Nb, Hf, or Mg. In other embodiments, CdO can be doped with In or Sn. In other embodiments, GaInO₃ can be doped with Sn or Ge. In other embodiments, CdSb₂O₃ can be doped with Y. In other embodiments, ITO can be doped with Sn. Other embodiments include still other TCO materials and corresponding dopants.

In some embodiments, the materials suitable for the chamber 128 and the diffuser head 110 are anodized aluminum, aluminum alloy, ceramic, and other corrosion resistant materials.

Throughout this disclosure “CIGS” generally refers to Copper-Indium-Gallium-Selenide or Cu(In,Ga)Se₂, which may also be represented as Cu(InₓGa_{y})Se₂.

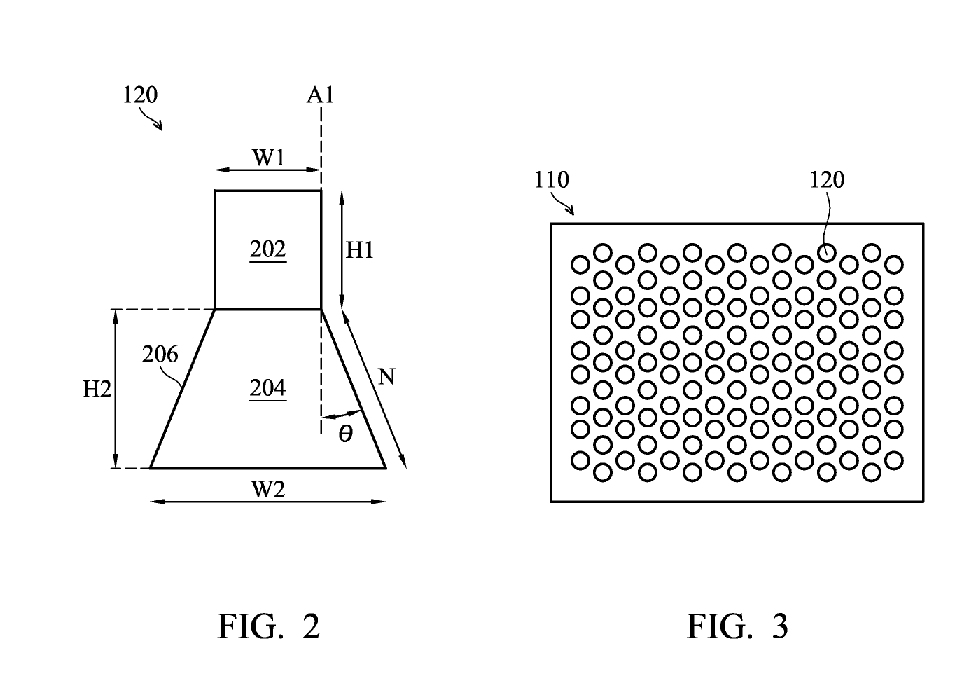

FIG. 2 is a schematic cross-section view of an exemplary diffuser head opening 120 in accordance with some embodiments. Each of the plurality of openings 120 in the diffuser head 110 comprises a first portion 202 and second portion 204. Both first portion 202 and second portion 204 are defined by the surfaces of openings 120 in diffuser head 110.

First portion is shaped as a cylinder having a width W1 and height H1. Second portion 204 is shaped as a conical frustum having a width W2, height H2, and length N. The surface 206 which defines second portion 204 is disposed at an angle θ relative to axis A1 which is defined by the surface normal of the plate 114.

First portion 202 and second portion 204 are fluidly coupled with each other and further fluidly coupled with supply plenum 118 and chamber 128. As described above with reference to FIG. 1, processing gas flows from supply plenum 118 through first portion 202 and second portion 204 and into chamber 128.

The nozzle configuration of opening 120 comprising cylindrically-shaped first portion 202 and second portion 204 shaped as a conical frustum is designed such that at least some of the processing gas leaving second portion 204 and entering chamber 128 has a greater horizontal velocity component than if second portion 204 were cylindrically-shaped. Thus the addition of frustum-shaped second portion 204 provides for more uniform distribution of processing gas within chamber 128 and, by consequence, more uniform distribution of processing gas onto substrate 122. For example, the gas can more readily be supplied to the regions between openings 120.

In some embodiments, second portion 204 has a parabolic or half hyperbolic cross section.

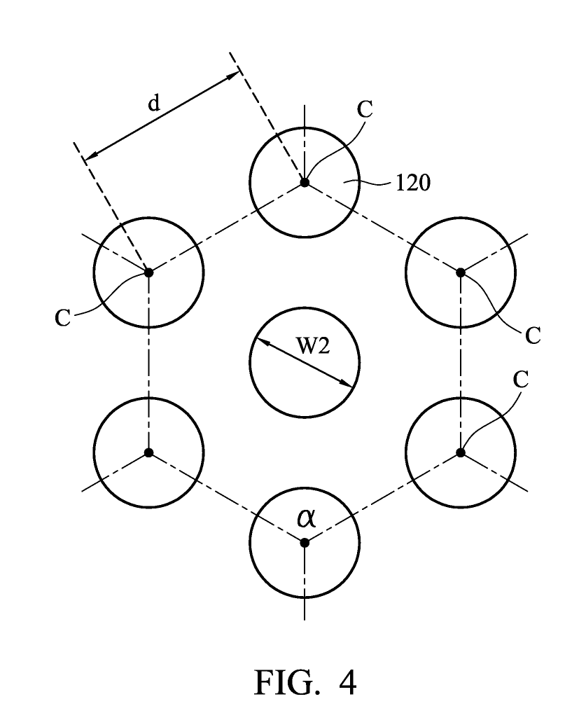

FIG. 3 is a plan view illustrating the configuration of diffuser head openings 120 in accordance with some embodiments. FIG. 4 is a plan view of a portion of a diffuser head 110 illustrating the configuration of diffuser head openings 120 in accordance with some embodiments.

Openings 120 are arranged in second plate 114 in a honeycomb pattern. A honeycomb pattern is identified as openings disposed in rows, with adjacent rows horizontally offset from each other by about one half the horizontal spacing between adjacent openings within a single one of the rows, as illustrated in FIG. 3.

In some embodiments, second plate 114 is rectangular shaped as illustrated in FIG. 3. In other embodiments, second plate 114 is square shaped or circular shaped.

FIG. 4 further illustrates the honeycomb pattern. FIG. 4 is illustrated as a plan view of the bottom of second plate 114; each opening thus has a diameter W2. Each opening 120 has a centerpoint C. Each centerpoint C is equidistant from the centerpoint C of each adjacent opening 120. This distance is indicated as distance d in FIG. 4. Each interior opening has six equally spaced adjacent openings. The openings at the perimeter of the second plate 114 can have fewer than six adjacent openings.

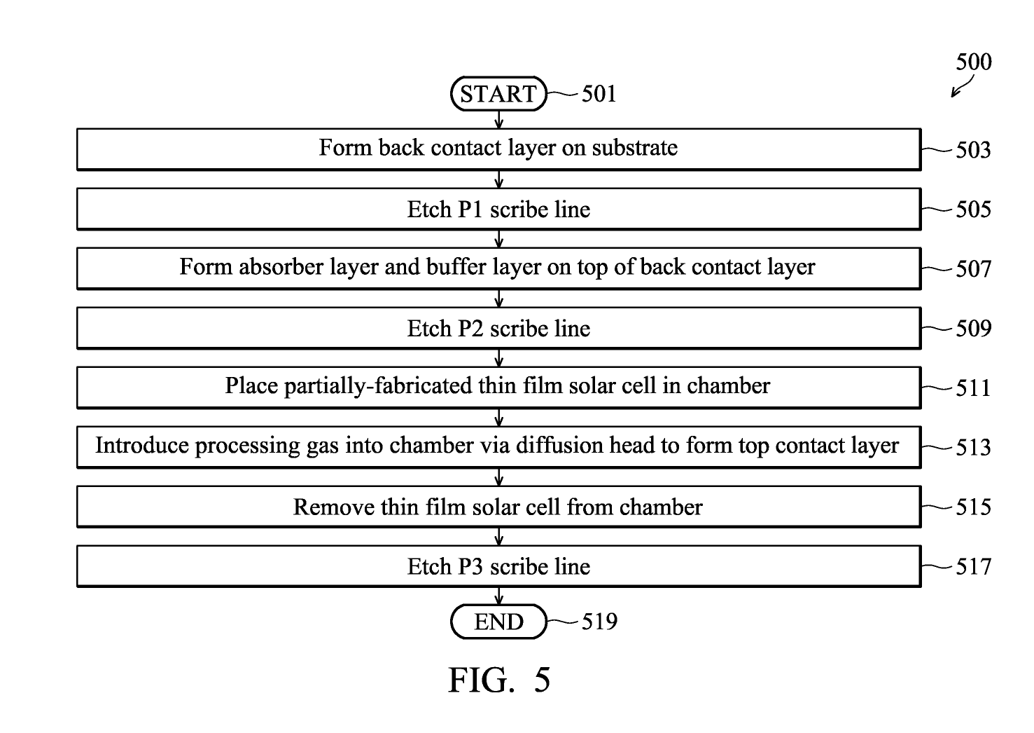

FIG. 5 is a flow chart of a method 500 of forming a thin film solar cell using diffuser head 110 in accordance with some embodiments. The method begins at block 501. At block 503 a back contact layer is formed on a substrate 122. The P1 scribe line is etched at block 505, and then at block 507 an absorber layer and buffer layer are formed above the back contact layer. The P2 scribe line is etched at block 509.

The partially-fabricated thin film solar cell comprising substrate 122, back contact layer, absorber layer, buffer layer, and P1 and P2 scribe lines is placed in chamber 128 at block 511. At block 513 a processing gas is introduced into the chamber 128 via diffusion head 110 to form a top contact layer. At block 515 the thin film solar cell is removed from the chamber 128 and the P3 line is etched at block 517.

Method 500 ends at block 519.

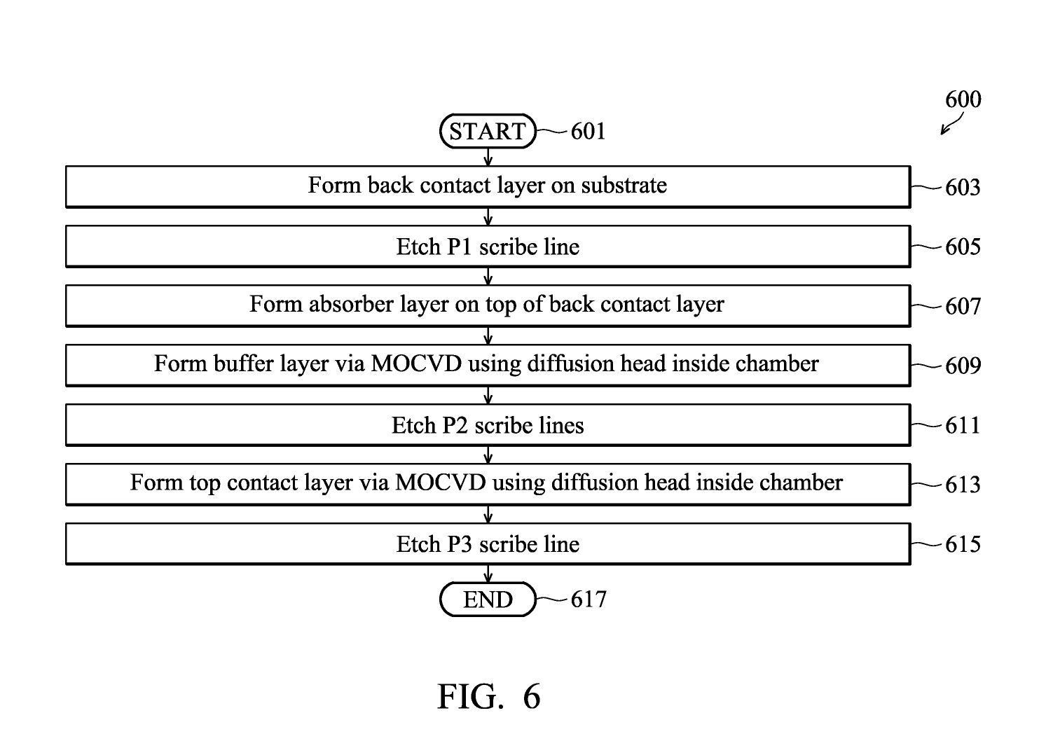

FIG. 6 is a flow chart of a method 600 of forming a thin film solar cell using diffuser head 110 in accordance with some embodiments. The method begins at block 601. At block 603 a back contact layer is formed on a substrate 122. The P1 scribe line is etched at block 605, and then at block 607 an absorber layer is formed above the back contact layer.

At block 609 the buffer layer is formed by placing the partially-fabricated thin film solar cell comprising substrate 122, back contact layer, absorber layer, and P1 scribe line into chamber 128. A processing gas is introduced into the chamber 128 via diffusion head 110 to form a buffer layer. The P2 scribe line is etched at block 611.

At block 613 the top contact layer is formed by placing the partially-fabricated thin film solar cell comprising substrate 122, back contact layer, absorber layer, buffer layer, and P1 and P2 scribe lines into chamber 128. A processing gas is introduced into the chamber 128 via diffusion head 110 to form a top contact layer. The P3 line is etched at block 615.

Method 600 ends at block 617.

Following fabrication, thin film solar cells are tested for quality assurance purposes. In some instances, only a representative sample of thin film solar cells fabricated at a facility are tested for quality assurance purposes. A thin film solar cell is evaluated to determine the thickness of the top contact layer, and the solar cell's transmittance, haze, and resistivity. Solar cells which fail to meet predetermined thresholds for any one of these measurements are discarded. The discarded solar cells are factored into a failure rate of the facility, which is inversely proportional to the throughput of that facility.

The present disclosure thus provides an apparatus and method of forming an improved top contact layer in a thin film solar cell. The appratus and method have several advantages. First, the conical frustum of second portion 204 causes processing gas to enter the chamber at an angle which improves horizontal diffusion of the processing gas across the surface of substrate 122. Second, the equidistant spacing of openings 120 in the diffuser head 110 improves processing gas distribution across the surface of substrate 122. As a result of these two features, a transparent conductive oxide layer formed using the disclosed apparatus and method is likely to have a more uniform thickness than layers similarly formed in the prior art. A more uniform thickness results in improved performance characteristics, notably a reduced resistivity, reduced haze, and increased transmittance. The improved performance results in a lower failure rate and thus a higher throughput during thin film solar cell manufacturing.

In some embodiments, a method of forming a thin film solar cell, comprises providing a partially-fabricated thin film solar cell comprising a substrate, a back contact layer, an absorber layer, and a buffer layer in a chamber; and introducing a processing gas into the chamber through a diffusion plate having a plurality of openings configured in a honeycomb pattern to form a top contact layer over the buffer layer, wherein each of said plurality of openings comprises a conical frustum portion. In some embodiments, the honeycomb pattern comprises said plurality of openings disposed in rows oriented in a first direction, wherein adjacent rows are offset from each other in the first direction. In some embodiments, the top contact layer is a transparent conductive oxide. In some embodiments, the absorber layer is a CIGS absorber. In some embodiments, the width of the bottom of the conical frustum portion for each of the plurality of openings is at least twice the width of the top of the cylindrical portion. In some embodiments, a first axis is normal to the surface of the diffusion plate and wherein an outer surface of the conical frustum portion is disposed at an angle between 0 and 60 degrees relative to the first axis. In some embodiments, each of said plurality of openings further comprises a cylindrical portion. In some embodiments, the top contact layer is formed by MOCVD. In some embodiments, the top contact layer is formed from a doped material.

In some embodiments, an apparatus for chemical vapor deposition during thin film solar cell manufacturing comprises a diffusion head comprising: a first plate; a second plate coupled to the first plate, the second plate having a plurality of openings configured in a honeycomb pattern with each of said plurality of openings comprising a conical frustum portion; and a supply plenum, defined between the first plate and the second plate, the supply plenum fluidly coupled to a first processing gas inlet. In some embodiments, the diffusion head is mounted in a chamber. In some embodiments, the apparatus further comprises a second processing gas inlet; and a mixing chamber fluidly coupled with the first processing gas inlet, the second processing gas inlet, and the supply plenum. In some embodiments, the honeycomb pattern comprises said plurality of openings disposed in rows oriented in a first direction, wherein adjacent rows are offset from each other in a second direction. In some embodiments, each of said plurality of openings further comprises a cylindrical portion. In some embodiments, the width of the bottom of the conical frustum portion for each of the plurality of openings is at least twice the width of the top of the cylindrical portion. In some embodiments, the chamber includes a stage facing the second plate.

In some embodiments an apparatus for chemical vapor deposition during thin film solar cell manufacturing comprises a diffusion head comprising a first plate; a second plate coupled to the first plate, the second plate having a plurality of openings configured in a honeycomb pattern with each of said plurality of openings comprising a cylindrical portion and a conical frustum portion; and a supply plenum, defined between the first plate and the second plate, the supply plenum fluidly coupled to first processing gas inlet; and a chamber, wherein the diffusion head is mounted in the chamber. In some embodiments, the first processing gas inlet is operably connected to a processing gas source. In some embodiments, each of the plurality of openings has a centerpoint, and wherein a centerpoint of an opening is equidistant from the centerpoint of each adjacent opening. In some embodiments, the apparatus further comprises a second processing gas inlet; and a mixing chamber fluidly coupled with the first processing gas inlet, the second processing gas inlet, and the supply plenum.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. (canceled)

2. (canceled)

3. (canceled)

4. (canceled)

5. (canceled)

6. (canceled)

7. (canceled)

8. (canceled)

9. (canceled)

10. An apparatus for chemical vapor deposition during thin film solar cell manufacturing, comprising:
a diffusion head comprising:
a first plate;
a second plate coupled to the first plate, the second plate having a plurality of openings configured in a honeycomb pattern with each of said plurality of openings comprising a conical frustum portion; and
a supply plenum, defined between the first plate and the second plate, the supply plenum fluidly coupled to a first processing gas inlet.

11. The apparatus of claim 10, wherein said diffusion head is mounted in a chamber.

12. The apparatus of claim 11, further comprising:
a second processing gas inlet; and
a mixing chamber fluidly coupled with the first processing gas inlet, the second processing gas inlet, and the supply plenum.

13. The apparatus of claim 11 wherein the honeycomb pattern comprises said plurality of openings disposed in rows oriented in a first direction, wherein adjacent rows are offset from each other in a second direction.

14. The apparatus of claim 13 wherein each of said plurality of openings further comprises a cylindrical portion.

15. The apparatus of claim 14 wherein the width of the bottom of the conical frustum portion for each of the plurality of openings is at least twice the width of the top of the cylindrical portion.

16. The apparatus of claim 15 wherein said chamber includes a stage facing the second plate.

17. An apparatus for chemical vapor deposition during thin film solar cell manufacturing, comprising:
a diffusion head comprising:
a first plate;
a second plate coupled to the first plate, the second plate having a plurality of openings configured in a honeycomb pattern with each of said plurality of openings comprising a cylindrical portion and a conical frustum portion; and
a supply plenum, defined between the first plate and the second plate, the supply plenum fluidly coupled to first processing gas inlet; and
a chamber, wherein the diffusion head is mounted in the chamber.

18. The apparatus of claim 17 wherein the first processing gas inlet is operably connected to a processing gas source.

19. The apparatus of claim 17 wherein each of the plurality of openings has a centerpoint, and wherein a centerpoint of an opening is equidistant from the centerpoint of each adjacent opening.

20. The apparatus of claim 19, further comprising:
a second processing gas inlet; and
a mixing chamber fluidly coupled with the first processing gas inlet, the second processing gas inlet, and the supply plenum.

21. The apparatus of claim 15, wherein a first axis is normal to a surface of the second plate and wherein an outer surface of each conical frustum portion is disposed at an angle between 0 and 60 degrees relative to the first axis.

22. The apparatus of claim 15, wherein a first axis is normal to a surface of the second plate and wherein an outer surface of each conical frustum portion is disposed at an angle between 30 and 45 degrees relative to the first axis.

23. The apparatus of claim 14, wherein each cylindrical portion is disposed on the same side of said second plate as the supply plenum and said conical frustum portion is disposed on a side of the second plate opposite the supply plenum.

24. The apparatus of claim 20 wherein the second processing gas inlet is operably connected to a processing gas source.

25. The apparatus of claim 24 wherein the first processing gas inlet is operably connected to a processing gas source which is different from the processing gas source operably connected to the second processing gas inlet.

26. The apparatus of claim 17, wherein a first axis is normal to a surface of the second plate and wherein an outer surface of each conical frustum portion is disposed at an angle between 0 and 60 degrees relative to the first axis.

27. The apparatus of claim 17, wherein a first axis is normal to a surface of the second plate and wherein an outer surface of each conical frustum portion is disposed at an angle between 20 and 30 degrees relative to the first axis.

28. A system of chemical vapor deposition during thin film solar cell manufacturing, comprising:
a first processing gas source fluidly coupled to a first processing gas inlet;
a supply plenum fluidly coupled to the first processing gas inlet, said supply plenum defined by a first plate and a second plate having a plurality of openings configured in a honeycomb pattern with each of said plurality of openings comprising a cylindrical portion and a conical frustum portion, wherein said first and second plate are disposed within a processing gas chamber having an evacuation port, and wherein each of the plurality of openings has a centerpoint, and wherein a centerpoint of each one of the openings is equidistant from a centerpoint of each of the openings adjacent to that one opening;
a stage disposed within the processing gas chamber adapted to receive at least a substrate of a thin film solar cell.

29. The system of claim 28 further comprising:
a second processing gas source fluidly coupled to a second processing gas inlet, wherein each of said first processing gas inlet and said second processing gas inlet are fluidly coupled to a mixing chamber and said mixing chamber is fluidly coupled to the supply plenum.
